(19) United States
(12) Patent Application Publication
(10) Pub. No.: US 2025/0201486 A1
(43) Pub. Date: Jun. 19, 2025

(54) CAPACITOR EMBEDDED SUBSTRATE

(71) Applicant: Murata Manufacturing Co., Ltd., Nagaokakyo-shi (JP)

(72) Inventor: Akitomo TAKAHASHI, Nagaokakyo-shi (JP)

(21) Appl. No.: 19/072,257

(22) Filed: Mar. 6, 2025

Related U.S. Application Data
(63) Continuation of application No. PCT/JP2024/025509, filed on Jul. 16, 2024.

(30) Foreign Application Priority Data
Jul. 28, 2023 (JP) 2023-123477

(51) Int. Cl. H01G 9/012; H01G 2/06; H01G 9/10

(52) U.S. Cl. CPC H01G 9/012; H01G 2/065; H01G 9/10

(57) ABSTRACT

A capacitor embedded substrate that includes: a wiring substrate; and a capacitor element embedded in the wiring substrate. The capacitor element includes a capacitor portion and a sealing layer covering the capacitor portion. At least one first capacitor through-hole and at least one second capacitor through-hole extend through the capacitor element. A capacitor through anode conductor is inside the first capacitor through-hole and connected to an anode plate of the capacitor portion. A first substrate through-hole is in the first capacitor through-hole and a second substrate through-hole is in the second capacitor through-hole, the first substrate through-hole and the second substrate through-hole extends through the wiring substrate and the capacitor element. A substrate through anode conductor is in the first substrate through-hole and electrically connected to the anode plate. A substrate through cathode conductor is in the second substrate through-hole and electrically connected to the cathode layer.

### CROSS REFERENCE TO RELATED APPLICATIONS

The present application is a continuation of International application No. PCT/JP2024/025509, filed Jul. 16, 2024, which claims priority to Japanese Patent Application No. 2023-123477, filed Jul. 28, 2023, the entire contents of each of which are incorporated herein by reference.

### TECHNICAL FIELD

The present disclosure relates to a capacitor embedded substrate.

### BACKGROUND ART

Patent Document 1 discloses a module including a capacitor layer including at least one capacitor portion forming a capacitor, a connection terminal, and a through-hole conductor formed to extend through the capacitor portion in a thickness direction of the capacitor layer. The through-hole conductor includes a first through-hole conductor formed in at least an inner wall surface of a first through-hole extending through the capacitor portion in the thickness direction. The first through-hole conductor is electrically connected to an anode of the capacitor portion. The capacitor portion includes an anode plate including metal. The first through-hole conductor is connected to an end surface of the anode plate. The module further includes an anode connection layer disposed between the first through-hole conductor and the end surface of the anode plate. The first through-hole conductor is connected to the end surface of the anode plate via the anode connection layer. When viewed in section in a direction orthogonal to the thickness direction, the first through-hole conductor of a portion where the anode connection layer is present protrudes inward in the first through-hole, as compared with the first through-hole conductor of another portion where the anode connection layer is not present.
Patent Document 1: Japanese Unexamined Patent Application Publication No. 2022-172255

### SUMMARY OF THE DISCLOSURE

In Patent Document 1, as an embodiment of a module, a capacitor embedded substrate in which a capacitor element is embedded in a wiring substrate is described.

In order to manufacture the capacitor embedded substrate described above, FIGS. 14A and 14B of the Patent Document 1 illustrate that through-holes 263 and 265 are formed in portions where through-hole conductors 262 and 264 are to be formed by drilling or laser machining, and inner surfaces of the through-holes 263 and 265 are then metallized by electroless Cu plating or the like, whereby the through-hole conductors 262 and 264 are formed.

At this time, for example, when the through-hole conductor 262 is formed so as to be connected to an end surface of an anode plate 231, the anode plate 231 and a conductive portion 220 are simultaneously exposed on an inner surface of the through-hole 263 for the through-hole conductor 262. However, in general, while the anode plate 231 includes a valve action metal such as aluminum (Al), the conductive portion 220 includes a metal such as copper (Cu), and thus it is difficult to form the through-hole conductor 262, using a general technique such as plating, on a surface of the through-hole 263 on which these different metals are exposed.

The present disclosure has been made to solve the above problem, and it is an object of the present disclosure to provide a capacitor embedded substrate including a capacitor through anode conductor connected to an end surface of an anode plate, the capacitor through anode conductor being able to be formed using a general technique.

A capacitor embedded substrate of the present disclosure includes: a wiring substrate; and a capacitor element embedded in the wiring substrate, the capacitor element including: a capacitor portion that includes an anode plate having a porous portion on at least one main surface of a core portion, a dielectric layer on a surface of the porous portion, and a cathode layer on a surface of the dielectric layer, and a sealing layer covering at least one main surface of the capacitor portion; at least one first capacitor through-hole and at least one second capacitor through-hole that do not extend through the wiring substrate but extend through the capacitor element in a thickness direction of the anode plate; a capacitor through anode conductor inside the first capacitor through-hole and electrically connected to an end surface of the anode plate; a first substrate through-hole on an inner side of the first capacitor through-hole and a second substrate through-hole on an inner side of the second capacitor through-hole, the first substrate through-hole and the second substrate through-hole extending through the wiring substrate and the capacitor element in the thickness direction of the anode plate; a substrate through anode conductor on an inner wall surface of the first substrate through-hole, on an inner side of the capacitor through anode conductor, and electrically connected to the anode plate; and a substrate through cathode conductor on an inner wall surface of the second substrate through-hole and electrically connected to the cathode layer.

According to the present disclosure, it is possible to provide a capacitor embedded substrate including a capacitor through anode conductor connected to an end surface of an anode plate, the capacitor through anode conductor being able to be formed using a general technique.

### BRIEF DESCRIPTION OF THE DRAWINGS

FIG. 1 is a sectional view schematically illustrating an example of a capacitor embedded substrate according to a first embodiment of the present disclosure.

FIG. 2 is a plan view taken along line A-A of the capacitor embedded substrate illustrated in FIG. 1.

FIG. 3 is a plan view taken along line B-B of the capacitor embedded substrate illustrated in FIG. 1.

FIGS. 4A to 4G are sectional views schematically illustrating an example of a method for manufacturing a capacitor element having a capacitor through anode conductor, of methods for manufacturing a capacitor embedded substrate within the scope of the present disclosure.

FIGS. 5A to 5C are sectional views schematically illustrating an example of a method for manufacturing the capacitor embedded substrate using the capacitor element having the capacitor through anode conductor.

FIGS. 6A to 6D are sectional views schematically illustrating an example of a method for manufacturing a capacitor element not having a capacitor through anode conductor, of methods for manufacturing a capacitor embedded substrate outside the scope of the present disclosure.

FIGS. 7A to 7C are sectional views schematically illustrating an example of a method for manufacturing a capacitor embedded substrate using the capacitor element not having a capacitor through anode conductor.

FIG. 8 is a sectional view schematically illustrating an example of a capacitor embedded substrate according to a second embodiment of the present disclosure.

FIG. 9 is a plan view taken along line A-A of the capacitor embedded substrate illustrated in FIG. 8.

FIG. 10 is a plan view taken along line B-B of the capacitor embedded substrate illustrated in FIG. 8.

FIG. 11 is a plan view schematically illustrating an example of a capacitor embedded substrate according to a third embodiment of the present disclosure.

FIG. 12 is a sectional view schematically illustrating an example of a capacitor embedded substrate according to a fourth embodiment of the present disclosure.

FIG. 13 is a sectional view schematically illustrating an example of a capacitor embedded substrate according to a fifth embodiment of the present disclosure.

### DESCRIPTION OF THE PREFERRED EMBODIMENTS

Hereinafter, a capacitor embedded substrate of the present disclosure will be described. Note that the present disclosure is not limited to the following embodiments, and appropriate modifications can be made without departing from the spirit of the present disclosure. Incidentally, combinations of two or more features appropriately selected from the following embodiments also fall within the scope of the present disclosure.

The following embodiments are mere examples, and it is obvious that features of embodiments may be partially substituted with features of other embodiments, and features of different embodiments may be combined. The second and later embodiments will be described, without repeating the descriptions of features shared with the first embodiment, but substantially with descriptions of differences from the first embodiment. In particular, the same advantages provided by the same features as in the first embodiment will not be repeatedly mentioned in the other embodiments.

In the following description, when no particular distinction is to be made between the embodiments, they are simply referred to as a “capacitor embedded substrate of the present disclosure”.

In this specification, a term indicating a relationship between elements (for example, the term “vertical”, “parallel”, “orthogonal”, or the like) and a term indicating a shape of an element are representations that mean to be substantially equivalent, for example, including approximately a few percentages different, rather than a representation indicating only a strict sense. Also, in this specification, “being equivalent” is a representation that means to be substantially equivalent, for example, including approximately a few percentages different, rather than a representation indicating only being perfectly equivalent.

The following drawings schematically illustrate the elements, and the drawing scales and the like of the sizes and the aspect ratios of the elements may be different from those of actual products. In the drawings, the same reference numerals are used for the same or corresponding portions. In addition, the same elements are denoted by the same reference numerals in the drawings, and duplicate explanation of the same elements is omitted.

### First Embodiment

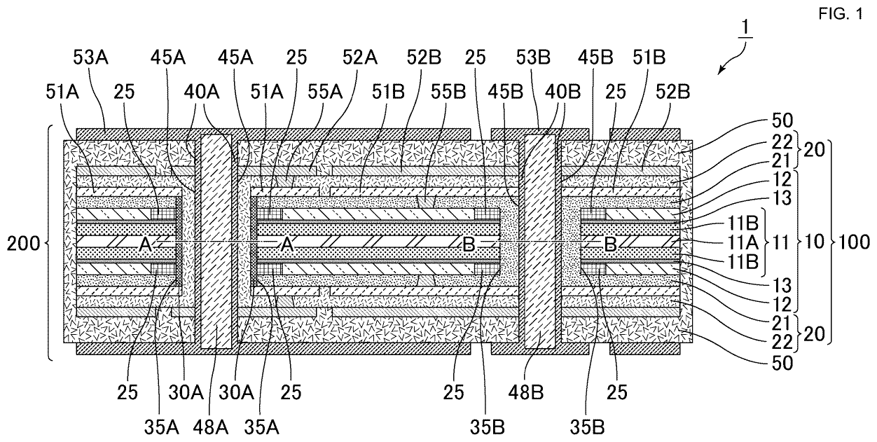

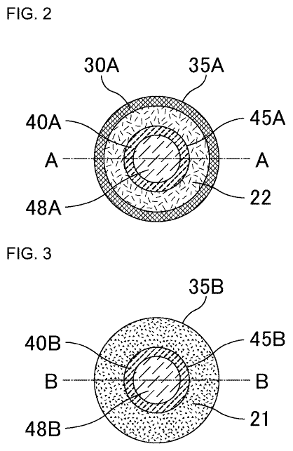

FIG. 1 is a sectional view schematically illustrating an example of a capacitor embedded substrate according to a first embodiment of the present disclosure. FIG. 2 is a plan view taken along line A-A of the capacitor embedded substrate illustrated in FIG. 1. FIG. 3 is a plan view taken along line B-B of the capacitor embedded substrate illustrated in FIG. 1.

A capacitor embedded substrate 1 illustrated in FIG. 1 includes a capacitor element 100 and a wiring substrate 200 in which the capacitor element 100 is embedded.

The capacitor element 100 includes a capacitor portion 10 and a sealing layer 20 that is provided so as to cover at least one main surface of the capacitor portion 10. In the example illustrated in FIG. 1, the sealing layer 20 includes a first sealing layer 21 that covers the capacitor portion 10 and a second sealing layer 22 that covers the first sealing layer 21.

In the example illustrated in FIG. 1, one capacitor portion 10 is disposed inside the sealing layer 20. The number of the capacitor portions 10 disposed inside the sealing layer 20 is not particularly limited and may be one, or two or more.

The capacitor portion 10 includes an anode plate 11 having a porous portion 11B on at least one main surface of a core portion 11A, a dielectric layer 13 provided on a surface of the porous portion 11B, and a cathode layer 12 provided on a surface of the dielectric layer 13. As a result, the capacitor portion 10 constitutes an electrolytic capacitor. In the example illustrated in FIG. 1, the anode plate 11 has the porous portions 11B on both main surfaces of the core portion 11A, but may have the porous portion 11B on only one of the main surfaces of the core portion 11A.

The cathode layer 12 includes, for example, a solid electrolyte layer provided on the surface of the dielectric layer 13. The cathode layer 12 preferably further includes a conductor layer provided on a surface of the solid electrolyte layer. When the cathode layer 12 includes the solid electrolyte layer, the capacitor portion 10 constitutes a solid electrolytic capacitor.

The sealing layer 20 may be formed of only one layer, or may be formed of two or more layers. When the sealing layer 20 is formed of two or more layers, the materials constituting the respective layers may be the same or may be different from each other.

As illustrated in FIG. 1, the sealing layers 20 are preferably provided on both main surfaces, of the capacitor portion 10, opposing to each other in a thickness direction. The sealing layers 20 protect the capacitor portion 10.

The capacitor embedded substrate 1 is provided with at least one first capacitor through-hole 35A and at least one second capacitor through-hole 35B that do not extend through the wiring substrate 200 but extend through the capacitor element 100 in a thickness direction of the anode plate 11 (an up-down direction in FIG. 1). The first capacitor through-hole 35A and the second capacitor through-hole 35B are disposed away from each other.

A planar shape of the first capacitor through-hole 35A (for example, a cross-sectional shape vertical to the thickness direction) is not particularly limited and is, for example, a circular shape. Similarly, a planar shape of the second capacitor through-hole 35B is not particularly limited and is, for example, a circular shape.

The first capacitor through-hole 35A is preferably present inside the cathode layer 12 in plan view in the thickness direction of the anode plate 11. Similarly, the second capacitor through-hole 35B is preferably present inside the cathode layer 12 in plan view in the thickness direction of the anode plate 11.

The number of the first capacitor through-holes 35A may be the same as the number of the second capacitor through-holes 35B, may be less than the number of the second capacitor through-holes 35B, or may be more than the number of the second capacitor through-holes 35B.

A diameter of each first capacitor through-hole 35A may be equivalent to a diameter of each second capacitor through-hole 35B, may be smaller than the diameter of the second capacitor through-hole 35B, or may be larger than the diameter of the second capacitor through-hole 35B.

In this specification, the diameter of a through-hole means a diameter when the planar shape thereof is a circular shape, and means an equivalent circle diameter when the planar shape is a shape other than a circular shape.

The diameter of the first capacitor through-hole 35A may be constant or may be different in a thickness direction. Similarly, the diameter of the second capacitor through-hole 35B may be constant or may be different in a thickness direction.

When a plurality of first capacitor through-holes 35A are provided, diameters of the first capacitor through-holes 35A may be the same, or some or all of the diameters of the first capacitor through-holes 35A may be different.

When a plurality of second capacitor through-holes 35B are provided, diameters of the second capacitor through-holes 35B may be the same, or some or all of the diameters of the second capacitor through-holes 35B may be different.

A capacitor through anode conductor 30A electrically connected to an end surface of the anode plate 11 is provided inside each of the first capacitor through-hole 35A.

In other words, the capacitor through anode conductor 30A is electrically connected to the anode plate 11 in an inner wall surface of the first capacitor through-hole 35A. Therefore, an insulating material such as the sealing layer 20 is not filled between the capacitor through anode conductor 30A and the end surface of the anode plate 11.

The core portion 11A and the porous portion 11B are preferably exposed on the end surface of the anode plate 11 electrically connected to the capacitor through anode conductor 30A. In this case, in addition to the core portion 11A, the porous portion 11B is also electrically connected to the capacitor through anode conductor 30A.

As illustrated in FIG. 2, when viewed in the thickness direction of the anode plate 11, the capacitor through anode conductor 30A is preferably electrically connected to the anode plate 11 over an entire circumference of the first capacitor through-hole 35A.

The capacitor through anode conductor 30A may be electrically connected to the end surface of the anode plate 11 via an anode connection layer, or may be directly connected to the end surface of the anode plate 11.

When the plurality of first capacitor through-holes 35A is provided, the first capacitor through-hole 35A not having the capacitor through anode conductor 30A inside may be included, but it is preferable that the capacitor through anode conductor 30A is provided inside each of the plurality of first capacitor through-holes 35A.

Moreover, in the capacitor embedded substrate 1, a first substrate through-hole 45A is provided on an inner side of the first capacitor through-hole 35A, and a second substrate through-hole 45B is provided on an inner side of the second capacitor through-hole 35B, the first substrate through-hole 45A and the second substrate through-hole 45B extending through the wiring substrate 200 and the capacitor element 100 in the thickness direction of the anode plate 11.

A planar shape of the first substrate through-hole 45A is not particularly limited and is, for example, a circular shape. Similarly, a planar shape of the second substrate through-hole 45B is not particularly limited and is, for example, a circular shape.

When the plurality of first capacitor through-holes 35A is provided, the first capacitor through-hole 35A not having the first substrate through-hole 45A on the inner side may be included, but it is preferable that the first substrate through-hole 45A is provided on the inner side of each of the plurality of first capacitor through-holes 35A. Similarly, when the plurality of second capacitor through-holes 35B is provided, the second capacitor through-hole 35B not having the second substrate through-hole 45B on the inner side may be included, but it is preferable that the second substrate through-hole 45B is provided on the inner side of each of the plurality of second capacitor through-holes 35B.

A diameter of the first substrate through-hole 45A is not particularly limited as long as the diameter of the first substrate through-hole 45A is smaller than the diameter of the first capacitor through-hole 35A. Similarly, a diameter of the second substrate through-hole 45B is not particularly limited as long as the diameter of the second substrate through-hole 45B is smaller than the diameter of the second capacitor through-hole 35B.

The diameter of the first substrate through-hole 45A may be equivalent to the diameter of the second substrate through-hole 45B, may be smaller than the diameter of the second substrate through-hole 45B, or may be larger than the diameter of the second substrate through-hole 45B.

The diameter of the first substrate through-hole 45A may be constant or may be different in a thickness direction. Similarly, the diameter of the second substrate through-hole 45B may be constant or may be different in a thickness direction.

When a plurality of first substrate through-holes 45A is provided, diameters of the first substrate through-holes 45A may be the same, or some or all of the diameters of the first substrate through-holes 45A may be different.

When a plurality of second substrate through-holes 45B is provided, diameters of the second substrate through-holes 45B may be the same, or some or all of the diameters of the second substrate through-holes 45B may be different.

An inner wall surface of each first substrate through-hole 45A is provided with a substrate through anode conductor 40A electrically connected to the anode plate 11. An inner wall surface of each second substrate through-hole 45B is provided with a substrate through cathode conductor 40B electrically connected to the cathode layer 12.

As illustrated in FIGS. 1 and 2, the substrate through anode conductor 40A is located on an inner side of the capacitor through anode conductor 30A.

As will be described later, after the capacitor through anode conductor 30A is formed so as to be connected to the end surface of the anode plate 11, the substrate through anode conductor 40A is formed on the inner side of the capacitor through anode conductor 30A, and thus a metal constituting the anode plate 11 is not exposed on an inner surface of the first substrate through-hole 45A for forming the substrate through anode conductor 40A. Therefore, the substrate through anode conductor 40A can be easily formed by using a general technique such as plating.

Note that even in a case where the substrate through anode conductor 40A is formed at a position different from the capacitor through anode conductor 30A after the capacitor through anode conductor 30A is formed, the metal constituting the anode plate 11 is not exposed on the inner surface of the first substrate through-hole 45A for forming the substrate through anode conductor 40A. However, in this case, regions where functions as a capacitor are exhibited are reduced, and the capacitance is lowered, whereby the capacitor performance is decreased. On the other hand, when the substrate through anode conductor 40A is formed on the inner side of the capacitor through anode conductor 30A, regions where the functions as a capacitor are not exhibited are reduced, a decrease in capacitor performance can be suppressed.

As illustrated in FIG. 2, when viewed in the thickness direction of the anode plate 11, the substrate through anode conductor 40A is preferably provided over an entire circumference of an inner wall surface of the first substrate through-hole 45A.

As illustrated in FIG. 3, when viewed in the thickness direction of the anode plate 11, the substrate through cathode conductor 40B is preferably provided over an entire circumference of an inner wall surface of the second substrate through-hole 45B.

As illustrated in FIGS. 2 and 3, a diameter of the substrate through anode conductor 40A is preferably equivalent to a diameter of the substrate through cathode conductor 40B. The diameter of the substrate through anode conductor 40A may be smaller than the diameter of the substrate through cathode conductor 40B, or may be larger than the diameter of the substrate through cathode conductor 40B.

In this specification, the diameter of a through-conductor means a diameter when the planar shape thereof is a circular shape, and means an equivalent circle diameter when the planar shape is a shape other than a circular shape.

In particular, when viewed in the thickness direction of the anode plate 11, an area of the substrate through anode conductor 40A is preferably equivalent to an area of the substrate through cathode conductor 40B. The area of the substrate through anode conductor 40A may be smaller than the area of the substrate through cathode conductor 40B, or may be larger than the area of the substrate through cathode conductor 40B.

A material constituting the substrate through anode conductor 40A may be the same as or different from a material constituting the substrate through cathode conductor 40B.

A material constituting the capacitor through anode conductor 30A may be the same as or different from a material constituting the substrate through anode conductor 40A.

As illustrated in FIG. 1, an insulating material such as the sealing layer 20 is preferably filled between the substrate through anode conductor 40A and the capacitor through anode conductor 30A. In the example illustrated in FIG. 1, the second sealing layer 22 is filled between the substrate through anode conductor 40A and the capacitor through anode conductor 30A.

In addition, an insulating material such as the sealing layer 20 is preferably filled between the substrate through cathode conductor 40B and the end surface of the anode plate 11. In the example illustrated in FIG. 1, the first sealing layer 21 is filled between the substrate through cathode conductor 40B and the end surface of the anode plate 11.

As illustrated in FIG. 1, the capacitor element 100 may further include an insulating mask layer 25, on at least one main surface of the anode plate 11, provided around the first capacitor through-hole 35A. The insulating mask layer 25 provided around the first capacitor through-hole 35A is preferably provided between the capacitor through anode conductor 30A and the cathode layer 12.

In addition, the capacitor element 100 may further include the insulating mask layer 25, on at least one main surface of the anode plate 11, provided around the second capacitor through-hole 35B. The insulating mask layer 25 provided around the second capacitor through-hole 35B is preferably provided between the insulating material (the first sealing layer 21 in FIG. 1), which is filled between the substrate through cathode conductor 40B and the capacitor portion 10, and the cathode layer 12.

Although not illustrated in FIG. 1, the capacitor portion 10 may further include, on at least one main surface of the anode plate 11, the insulating mask layer 25 provided so as to surround a periphery of the cathode layer 12. When the periphery of the cathode layer 12 is surrounded by the insulating mask layer 25, insulation between the anode plate 11 and the cathode layer 12 is ensured, and short-circuiting between the anode plate 11 and the cathode layer 12 is prevented. The insulating mask layer 25 may be provided so as to surround a part of the periphery of the cathode layer 12, but may be provided so as to surround the entire periphery of the cathode layer 12.

As illustrated in FIG. 1, a first resin filling portion 48A filled with a resin material may be provided on an inner side of the substrate through anode conductor 40A. In this case, the first resin filling portion 48A is provided in a space surrounded by the substrate through anode conductor 40A inside the first substrate through-hole 45A. When the space inside the first substrate through-hole 45A is eliminated by the provided first resin filling portion 48A, occurrence of delamination of the substrate through anode conductor 40A is suppressed. Note that the first resin filling portion 48A may be a conductor or may be an insulator.

In addition, a second resin filling portion 48B filled with a resin material may be provided on an inner side of the substrate through cathode conductor 40B. In this case, the second resin filling portion 48B is provided in a space surrounded by the substrate through cathode conductor 40B inside the second substrate through-hole 45B. When the space inside the second substrate through-hole 45B is eliminated by the provided second resin filling portion 48B, occurrence of delamination of the substrate through cathode conductor 40B is suppressed. Note that the second resin filling portion 48B may be a conductor or may be an insulator.

In the example illustrated in FIG. 1, first wiring layers 51A and 51B are provided between the first sealing layer 21 and the second sealing layer 22, and the second wiring layers 52A and 52B are provided on a surface of the second sealing layer 22.

In FIG. 1, the first wiring layers 51A and 51B are provided on both an upper side and a lower side of the capacitor element 100, but may be provided on only one of the upper side and the lower side. Similarly, the second wiring layers 52A and 52B are provided on both the upper side and the lower side of the capacitor element 100, but may be provided on only one of the upper side and the lower side.

The wiring substrate 200 includes, for example, a sealing insulating layer 50. In the example illustrated in FIG. 1, the wiring substrate 200 includes the sealing insulating layer 50 formed of one layer.

The sealing insulating layer 50 may be formed of only one layer, or may be formed of two or more layers. When the sealing insulating layer 50 is formed of two or more layers, the materials constituting the respective layers may be the same or may be different from each other. The sealing insulating layer 50 may be made of the same material as a material constituting the sealing layer 20, or may be made of a different material from the material constituting the sealing layer 20.

As illustrated in FIG. 1, the sealing insulating layers 50 are preferably provided on both main surfaces, of the capacitor element 100, opposing to each other in a thickness direction. As illustrated in FIG. 1, in addition to both the main surfaces of the capacitor element 100, at least a part of a side surface of the capacitor element 100 is preferably covered with the sealing insulating layer 50.

In the example illustrated in FIG. 1, third wiring layers 53A and 53B are provided on a surface of the sealing insulating layer 50.

In FIG. 1, the third wiring layers 53A and 53B may be provided on both the upper side and the lower side of the capacitor element 100, but may be provided on only one of the upper side and the lower side.

The first wiring layer 51A is electrically connected to the capacitor through anode conductor 30A. In the example illustrated in FIG. 1, the first wiring layer 51A is connected to an end portion of the capacitor through anode conductor 30A.

The second wiring layer 52A is electrically connected to the first wiring layer 51A. The second wiring layer 52A is connected to, for example, the first wiring layer 51A via an anode via conductor 55A extending through the second sealing layer 22.

Moreover, the second wiring layer 52A is electrically connected to the substrate through anode conductor 40A. In the example illustrated in FIG. 1, the substrate through anode conductor 40A is connected to an end portion of the second wiring layer 52A.

The third wiring layer 53A is electrically connected to the substrate through anode conductor 40A. In the example illustrated in FIG. 1, the third wiring layer 53A is connected to an end portion of the substrate through anode conductor 40A.

As described above, the third wiring layer 53A is electrically connected to the anode plate 11 via the substrate through anode conductor 40A, the second wiring layer 52A, the anode via conductor 55A, the first wiring layer 51A, and the capacitor through anode conductor 30A.

The first wiring layer 51B is electrically connected to the cathode layer 12. The first wiring layer 51B is connected to, for example, the cathode layer 12 via a cathode via conductor 55B extending through the first sealing layer 21.

Moreover, the first wiring layer 51B is electrically connected to the substrate through cathode conductor 40B. In the example illustrated in FIG. 1, the substrate through cathode conductor 40B is connected to an end portion of the first wiring layer 51B.

The second wiring layer 52B is electrically connected to the substrate through cathode conductor 40B. In the example illustrated in FIG. 1, the substrate through cathode conductor 40B is connected to an end portion of the second wiring layer 52B. Although not illustrated in FIG. 1, the second wiring layer 52B may be connected to the first wiring layer 51B via a cathode via conductor, extending through the second sealing layer 22.

The third wiring layer 53B is electrically connected to the substrate through cathode conductor 40B. In the example illustrated in FIG. 1, the third wiring layer 53B is connected to an end portion of the substrate through cathode conductor 40B.

As described above, the third wiring layer 53B is electrically connected to the cathode layer 12 via the substrate through cathode conductor 40B, the second wiring layer 52B, the first wiring layer 51B, and the cathode via conductor 55B.

The capacitor embedded substrate 1 illustrated in FIG. 1 is, for example, manufactured by the following method.

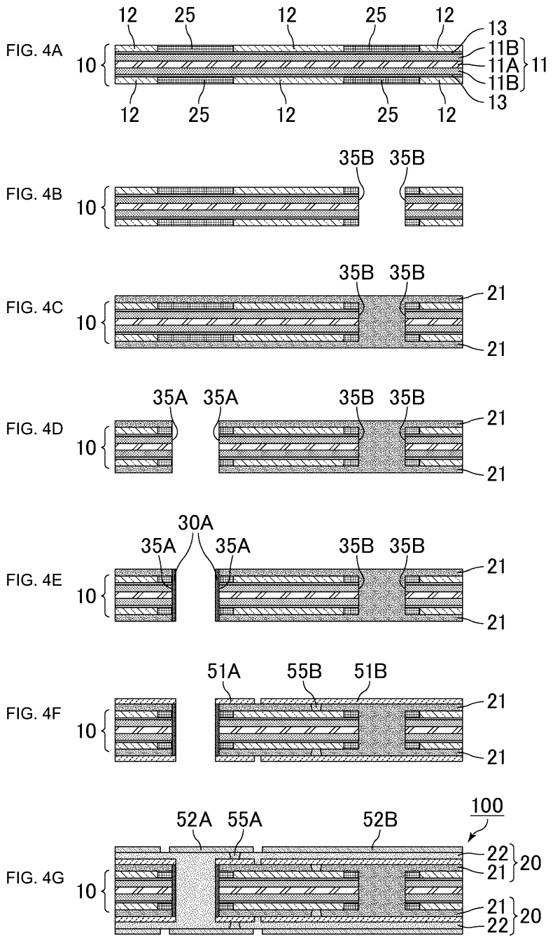

FIGS. 4A to 4G are sectional views schematically illustrating an example of a method for manufacturing a capacitor element having a capacitor through anode conductor, of methods for manufacturing a capacitor embedded substrate within the scope of the present disclosure.

In FIG. 4A, the capacitor portion 10 is prepared.

For example, through anodization of the anode plate 11 having the porous portion 11B on at least one main surface of the core portion 11A, the dielectric layer 13 is formed on a surface of the porous portion 11B.

Alternatively, as the anode plate 11 having the dielectric layer 13 provided on a surface of the porous portion 11B, a chemically formed foil may be prepared.

Next, the insulating mask layer 25 is formed in each of regions including portions where the first capacitor through-hole 35A (see FIG. 4D) and the second capacitor through-hole 35B (see FIG. 4B) are to be formed. For example, through coating of a surface of the dielectric layer 13 with an insulating resin by a method such as screen printing or using a dispenser, the insulating mask layer 25 is formed in each of the predetermined regions.

Subsequently, the cathode layer 12 is formed in each of regions, of the surface of the dielectric layer 13, not provided with the insulating mask layer 25. For example, as the cathode layer 12, a solid electrolyte layer and a conductor layer are formed in order on the surface of the dielectric layer 13. The capacitor portion 10 is obtained in the above-described manner.

In FIG. 4B, the second capacitor through-hole 35B is formed so as to extend through the capacitor portion 10.

For example, through performing of processing such as drilling or laser machining, the second capacitor through-hole 35B that extends through the insulating mask layer 25 and the anode plate 11 in the thickness direction is formed.

In FIG. 4C, each main surface of the capacitor portion 10 is covered with the first sealing layer 21. As illustrated in FIG. 4C, the second capacitor through-hole 35B is preferably filled with the first sealing layer 21.

In FIG. 4D, the first capacitor through-hole 35A is formed so as to extend through the capacitor portion 10 and the first sealing layer 21.

For example, through performing of processing such as drilling or laser machining, the first capacitor through-hole 35A that extends through the first sealing layer 21, the insulating mask layer 25, and the anode plate 11 in the thickness direction is formed.

As illustrated in FIG. 4D, a metal other than the anode plate 11 is not exposed on an inner surface of the first capacitor through-hole 35A.

In FIG. 4E, the capacitor through anode conductor 30A is formed on an inner wall surface of the first capacitor through-hole 35A.

For example, through metallizing of the inner wall surface of the first capacitor through-hole 35A with a low-resistance metal such as copper, gold, or silver, the capacitor through anode conductor 30A is formed. When the capacitor through anode conductor 30A is formed, for example, the inner wall surface of the first capacitor through-hole 35A is metallized by processing such as electroless Cu plating or electrolytic Cu plating for ease of processing. Note that the method for forming the capacitor through anode conductor 30A may be a method for filling the first capacitor through-hole 35A with a metal, a composite material of a metal and a resin, or the like in addition to the method for metallizing the inner wall surface of the first capacitor through-hole 35A.

The capacitor through anode conductor 30A connected to the end surface of the anode plate 11 is formed in the above-described manner.

In FIG. 4F, the cathode via conductor 55B, the first wiring layer 51A and the first wiring layer 51B are formed in predetermined regions.

The cathode via conductor 55B is formed as follows, for example: after a through-hole extending through the first sealing layer 21 in a thickness direction is formed, plating is performed on an inner wall surface of the through-hole using a low-resistance metal such as copper, gold, or silver, or the through-hole is filled with a conductive paste and heat treatment is then performed.

The first wiring layer 51A and the first wiring layer 51B are formed through, for example, plating on a surface of the first sealing layer 21.

In FIG. 4G, the first sealing layer 21, the first wiring layer 51A and the first wiring layer 51B are covered with the second sealing layer 22, whereby the sealing layer 20 is formed. As illustrated in FIG. 4G, the first capacitor through-hole 35A is preferably filled with the second sealing layer 22. Thereafter, the anode via conductor 55A, the second wiring layer 52A and the second wiring layer 52B are formed in predetermined regions.

The anode via conductor 55A is formed as follows, for example: after a through-hole extending through the second sealing layer 22 in a thickness direction is formed, plating is performed on an inner wall surface of the through-hole using a low-resistance metal such as copper, gold, or silver, or the through-hole is filled with a conductive paste and heat treatment is then performed.

The second wiring layer 52A and the second wiring layer 52B are formed through, for example, plating on a surface of the second sealing layer 22.

The capacitor element 100 is manufactured in the above-described manner.

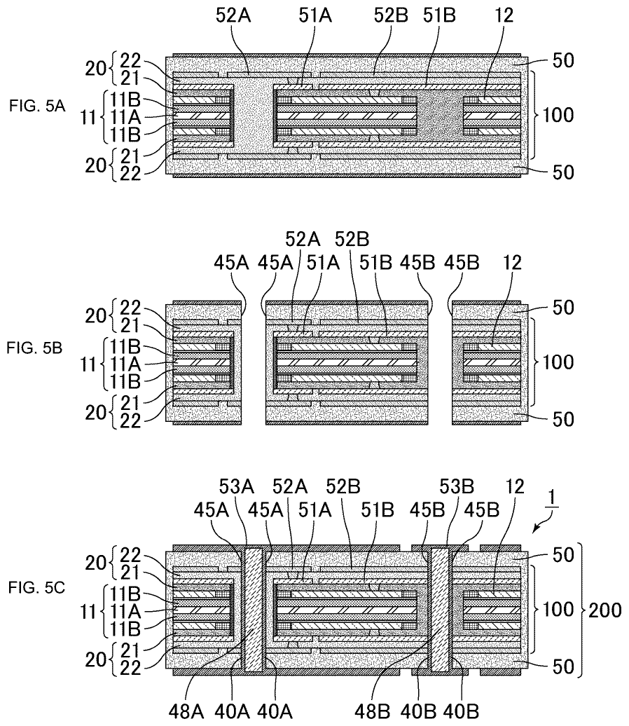

FIGS. 5A to 5C are sectional views schematically illustrating an example of a method for manufacturing the capacitor embedded substrate using the capacitor element having the capacitor through anode conductor.

In FIG. 5A, the capacitor element 100 is covered with the sealing insulating layer 50.

For example, the capacitor element 100 is covered using a sealing material having a surface provided with a metal foil such as a copper foil, whereby the sealing insulating layer 50 is formed.

In FIG. 5B, the first substrate through-hole 45A and the second substrate through-hole 45B are formed so as to extend through the sealing insulating layer 50, the sealing layer 20, and the capacitor portion 10.

For example, the first substrate through-hole 45A is formed through performing of processing such as drilling or laser machining on the inner side of the first capacitor through-hole 35A. At this time, the diameter of the first substrate through-hole 45A is made smaller than the diameter of the first capacitor through-hole 35A, and thus, in a surface direction, an insulating material such as the second sealing layer 22 is present between the inner wall surface of the first capacitor through-hole 35A and the inner wall surface of the first substrate through-hole 45A.

Similarly, the second substrate through-hole 45B is formed through performing of processing such as drilling or laser machining on the inner side of the second capacitor through-hole 35B. At this time, the diameter of the second substrate through-hole 45B is made smaller than the diameter of the second capacitor through-hole 35B, and thus, in a surface direction, an insulating material such as the first sealing layer 21 is present between the inner wall surface of the second capacitor through-hole 35B and the inner wall surface of the second substrate through-hole 45B.

As illustrated in FIG. 5B, the anode plate 11 is not exposed on the inner surface of the first substrate through-hole 45A or an inner surface of the second substrate through-hole 45B, and only a metal constituting a wiring layer such as the second wiring layer 52A is exposed.

In FIG. 5C, the substrate through anode conductor 40A is formed on the inner wall surface of the first substrate through-hole 45A, and the substrate through cathode conductor 40B is formed on the inner wall surface of the second substrate through-hole 45B.

For example, through metallizing of the inner wall surface of the first substrate through-hole 45A with a low-resistance metal such as copper, gold, or silver, the substrate through anode conductor 40A is formed. When the substrate through anode conductor 40A is formed, for example, the inner wall surface of the first substrate through-hole 45A is metallized by processing such as electroless Cu plating or electrolytic Cu plating for ease of processing. Note that the method for forming the substrate through anode conductor 40A may be a method for filling the first substrate through-hole 45A with a metal, a composite material of a metal and a resin, or the like in addition to the method for metallizing the inner wall surface of the first substrate through-hole 45A. The same applies to the method for forming the substrate through cathode conductor 40B. The substrate through anode conductor 40A and the substrate through cathode conductor 40B may be simultaneously formed or may be separately formed.

As illustrated in FIG. 5C, it is preferable that the first resin filling portion 48A and the second resin filling portion 48B are formed and that the third wiring layer 53A and the third wiring layer 53B are formed.

The capacitor embedded substrate 1 in which the capacitor element 100 is embedded in the wiring substrate 200 is manufactured in the above-described manner.

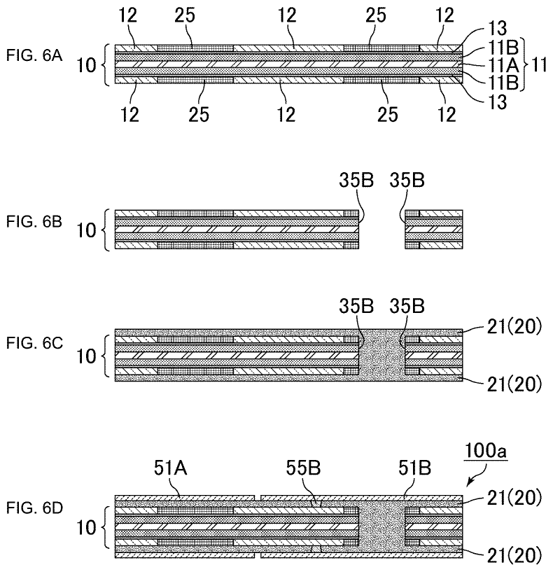

On the other hand, FIGS. 6A to 6D are sectional views schematically illustrating an example of a method for manufacturing a capacitor element not having a capacitor through anode conductor, of methods for manufacturing a capacitor embedded substrate outside the scope of the present disclosure.

In FIG. 6A, similarly to FIG. 4A, the capacitor portion 10 is prepared.

In FIG. 6B, similarly to FIG. 4B, the second capacitor through-hole 35B is formed so as to extend through the capacitor portion 10.

In FIG. 6C, similarly to FIG. 4C, each main surface of the capacitor portion 10 is covered with the first sealing layer 21. As illustrated in FIG. 6C, the second capacitor through-hole 35B is preferably filled with the first sealing layer 21. In the example illustrated in FIG. 6C, the sealing layer 20 is formed by the first sealing layer 21.

In FIG. 6D, similarly to FIG. 4F, the cathode via conductor 55B, the first wiring layer 51A and the first wiring layer 51B are formed at predetermined regions.

A capacitor element 100a is formed in the above-described manner.

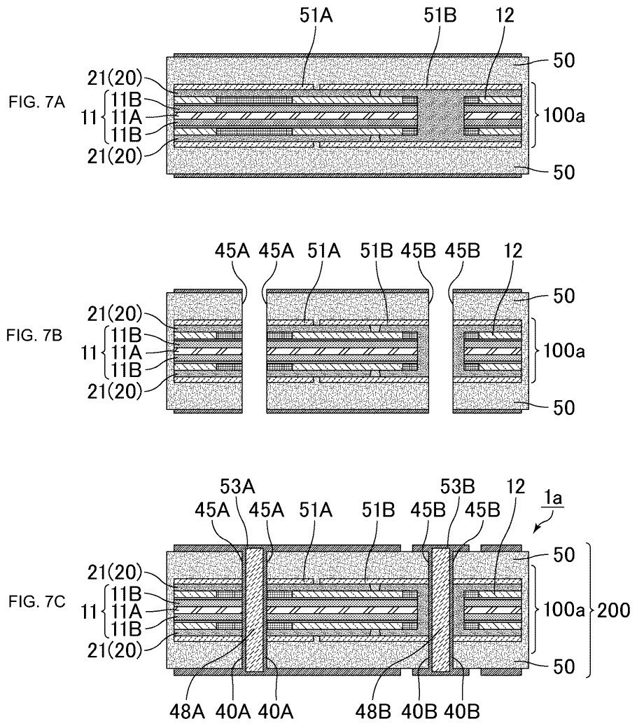

FIGS. 7A to 7C are sectional views schematically illustrating an example of a method for manufacturing a capacitor embedded substrate using the capacitor element not having a capacitor through anode conductor.

In FIG. 7A, similarly to FIG. 5A, the capacitor element 100a is covered with the sealing insulating layer 50.

In FIG. 7B, similarly to FIG. 5B, the first substrate through-hole 45A and the second substrate through-hole 45B are formed so as to extend through the sealing insulating layer 50, the sealing layer 20, and the capacitor portion 10.

In contrast to FIG. 5B, in FIG. 7B, not only the metal constituting the wiring layer such as the first wiring layer 51A, but also the anode plate 11 is exposed on the inner surface of the first substrate through-hole 45A.

In FIG. 7C, similarly to FIG. 5C, the substrate through anode conductor 40A is formed on the inner wall surface of the first substrate through-hole 45A, and the substrate through cathode conductor 40B is formed on the inner wall surface of the second substrate through-hole 45B.

A capacitor embedded substrate 1a in which the capacitor element 100a is embedded in the wiring substrate 200 is manufactured in the above-described manner.

As described above, in the method for manufacturing the capacitor embedded substrate 1a, since different metals are exposed on the inner surface of the first substrate through-hole 45A, it is difficult to form the substrate through anode conductor 40A by using a general technique such as plating.

On the other hand, in the method for manufacturing the capacitor embedded substrate 1, since different metals are not exposed on the inner surface of the first substrate through-hole 45A, the substrate through anode conductor 40A can be easily formed by using a general technique such as plating.

### Second Embodiment

In a capacitor embedded substrate according to a second embodiment of the present disclosure, a capacitor through cathode conductor is provided inside the second capacitor through-hole.

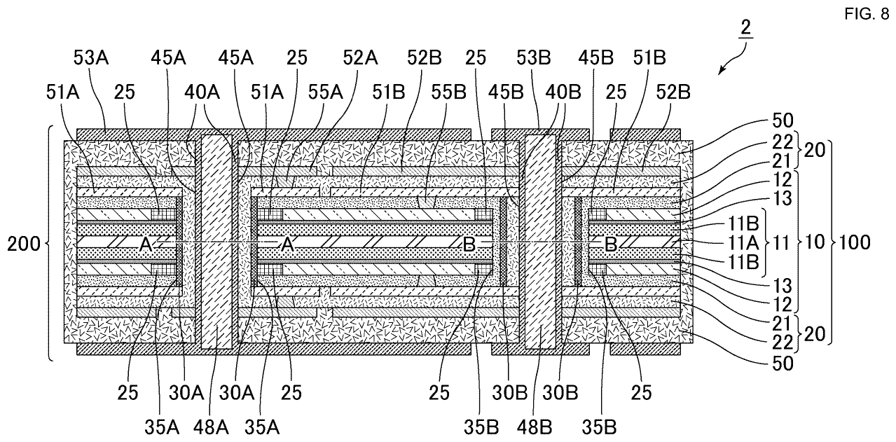

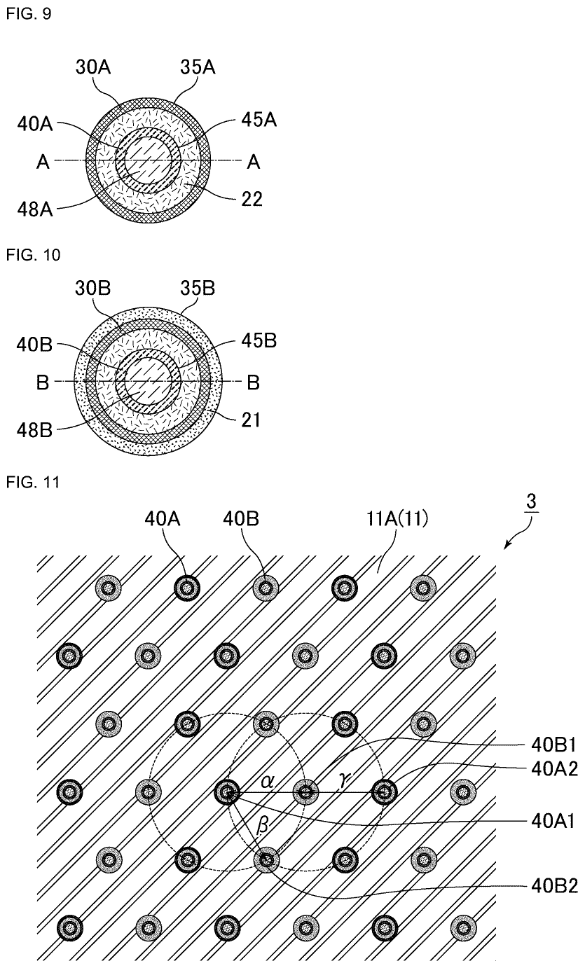

FIG. 8 is a sectional view schematically illustrating an example of the capacitor embedded substrate according to the second embodiment of the present disclosure. FIG. 9 is a plan view taken along line A-A of the capacitor embedded substrate illustrated in FIG. 8. FIG. 10 is a plan view taken along line B-B of the capacitor embedded substrate illustrated in FIG. 8.

In a capacitor embedded substrate 2 illustrated in FIG. 8, a capacitor through cathode conductor 30B not electrically connected to the anode plate 11, but electrically connected to the cathode layer 12 is provided inside the second capacitor through-hole 35B.

As illustrated in FIGS. 8 and 10, the substrate through cathode conductor 40B is located on an inner side of the capacitor through cathode conductor 30B.

The capacitor embedded substrate 2 illustrated in FIG. 8 includes a configuration in common with the capacitor embedded substrate 1 illustrated in FIG. 1 except for the capacitor through cathode conductor 30B.

In addition to the capacitor through anode conductor 30A provided inside the first capacitor through-hole 35A, the capacitor through cathode conductor 30B is provided inside the second capacitor through-hole 35B, whereby adhesion strength between the respective layers constituting the capacitor element 100 is further improved. As a result, a failure such as peeling between layers can be suppressed.

When a plurality of second capacitor through-holes 35B is provided, the second capacitor through-hole 35B not having the capacitor through cathode conductor 30B inside may be included, but the capacitor through cathode conductor 30B is preferably provided inside each of the plurality of second capacitor through-holes 35B.

As illustrated in FIG. 8, an insulating material such as the sealing layer 20 is preferably filled between the capacitor through cathode conductor 30B and an end surface of the anode plate 11. In the example illustrated in FIG. 8, the first sealing layer 21 is filled between the capacitor through cathode conductor 30B and the end surface of the anode plate 11.

In addition, an insulating material such as the sealing layer 20 is preferably filled between the substrate through cathode conductor 40B and the capacitor through cathode conductor 30B. For example, the same material as the first sealing layer 21 or the same material as the second sealing layer 22 may be filled between the substrate through cathode conductor 40B and the capacitor through cathode conductor 30B.

As illustrated in FIG. 10, when viewed in the thickness direction of the anode plate 11, the capacitor through cathode conductor 30B is preferably provided over an entire circumference along an outer periphery of the second capacitor through-hole 35B.

As illustrated in FIGS. 9 and 10, a diameter of the capacitor through anode conductor 30A is preferably equivalent to a diameter of the capacitor through cathode conductor 30B. The diameter of the capacitor through anode conductor 30A may be smaller than the diameter of the capacitor through cathode conductor 30B, or may be larger than the diameter of the capacitor through cathode conductor 30B.

In particular, when viewed in the thickness direction of the anode plate 11, an area of the capacitor through anode conductor 30A is preferably equivalent to an area of the capacitor through cathode conductor 30B. The area of the capacitor through anode conductor 30A may be smaller than the area of the capacitor through cathode conductor 30B, or may be larger than the area of the capacitor through cathode conductor 30B.

The material constituting the capacitor through anode conductor 30A may be the same as or different from a material constituting the capacitor through cathode conductor 30B.

The material constituting the capacitor through cathode conductor 30B may be the same as or different from the material constituting the substrate through cathode conductor 40B.

As illustrated in FIG. 8, the capacitor through cathode conductor 30B is preferably electrically connected to the first wiring layer 51B. In the example illustrated in FIG. 8, the first wiring layer 51B is connected to an end portion of the capacitor through cathode conductor 30B.

### Third Embodiment

In a capacitor embedded substrate according to a third embodiment of the present disclosure, in plan view in the thickness direction of the anode plate, a center-to-center distance between a first substrate through anode conductor and a first substrate through cathode conductor is equivalent to a center-to-center distance between the first substrate through anode conductor and a second substrate through cathode conductor, or the center-to-center distance between the first substrate through anode conductor and the first substrate through cathode conductor is equivalent to a center-to-center distance between a second substrate through anode conductor and the first substrate through cathode conductor.

In the third embodiment of the present disclosure, since a center-to-center distance between a substrate through anode conductor and a substrate through cathode conductor is made uniform, a difference in impedance between the respective current flow paths can be decreased. In addition, heat generation of the capacitor element can be dispersed, and a current capacitance can be increased.

In this specification, a center of the substrate through anode conductor or a center of the substrate through cathode conductor means a center of a minimum circle including the substrate through anode conductor or the substrate through cathode conductor, respectively, in plan view in the thickness direction of the anode plate. Therefore, the center-to-center distance between the substrate through anode conductor and the substrate through cathode conductor means a length of a line segment connecting the center of the substrate through anode conductor and the center of the substrate through cathode conductor obtained by the above-described method. The same applies to a center-to-center distance between a substrate through anode conductor and a substrate through anode conductor, and a center-to-center distance between a substrate through cathode conductor and a substrate through cathode conductor.

In the third embodiment of the present disclosure, the capacitor through cathode conductor does not have to be provided as in the first embodiment, or the capacitor through cathode conductor may be provided as in the second embodiment.

FIG. 11 is a plan view schematically illustrating an example of the capacitor embedded substrate according to the third embodiment of the present disclosure. The plan view illustrated in FIG. 11 is a plan view at the same position as FIGS. 2 and 3.

In a capacitor embedded substrate 3 illustrated in FIG. 11, the substrate through anode conductor 40A and the substrate through cathode conductor 40B are arranged so as to form a hexagonal pattern as a whole. In the hexagonal pattern arrangement, the substrate through anode conductor 40A or the substrate through cathode conductor 40B is disposed at each vertex of a regular hexagonal shape and in a center of the regular hexagonal shape. In the example illustrated in FIG. 11, the substrate through anode conductor 40A and the substrate through cathode conductor 40B are alternately arranged from a left side to a right side. Note that when the substrate through anode conductor 40A and the substrate through cathode conductor 40B are arranged so as to form a hexagonal pattern as a whole, arrangements of the substrate through anode conductor 40A and the substrate through cathode conductor 40B are not particularly limited, and for example, two substrate through anode conductors 40A and two substrate through cathode conductors 40B may be alternately arranged from the left side to the right side.

As illustrated in FIG. 11, in plan view in the thickness direction of the anode plate 11, a center-to-center distance between a first substrate through anode conductor 40A1 and a first substrate through cathode conductor 40B1 (a length α in FIG. 11) is preferably equivalent to a center-to-center distance between the first substrate through anode conductor 40A1 and a second substrate through cathode conductor 40B2 (a length β in FIG. 11).

In addition, in plan view in the thickness direction of the anode plate 11, the center-to-center distance between the first substrate through anode conductor 40A1 and the first substrate through cathode conductor 40B1 (the length α in FIG. 11) is preferably equivalent to a center-to-center distance between a second substrate through anode conductor 40A2 and the first substrate through cathode conductor 40B1 (a length γ in FIG. 11).

In contrast to the arrangement illustrated in FIG. 11, the substrate through anode conductor 40A and the substrate through cathode conductor 40B may be arranged so as to form a square pattern as a whole. In the square pattern arrangement, the substrate through anode conductor 40A or the substrate through cathode conductor 40B is disposed at each vertex of a square shape. For example, the substrate through anode conductor 40A and the substrate through cathode conductor 40B are alternately arranged from an upper side to a lower side, and at the same time, the substrate through anode conductor 40A and the substrate through cathode conductor 40B are alternately arranged from the left side to the right side. Note that when the substrate through anode conductor 40A and the substrate through cathode conductor 40B are arranged so as to form a square pattern as a whole, arrangements of the substrate through anode conductor 40A and the substrate through cathode conductor 40B are not particularly limited, and for example, two substrate through anode conductors 40A and two substrate through cathode conductors 40B may be alternately arranged from the upper side to the lower side, and at the same time, two substrate through anode conductors 40A and two substrate through cathode conductors 40B may be alternately arranged from the left side to the right side.

### Fourth Embodiment

In a capacitor embedded substrate according to a fourth embodiment of the present disclosure, a thickness of the wiring substrate is equal to or more than 2 times a thickness of the capacitor element.

In the fourth embodiment of the present disclosure, even when the capacitor element is thin, the wiring substrate is made thick, and thus the capacitor embedded substrate can be easily made thick at a low cost. As a result, the rigidity of the capacitor embedded substrate can be increased.

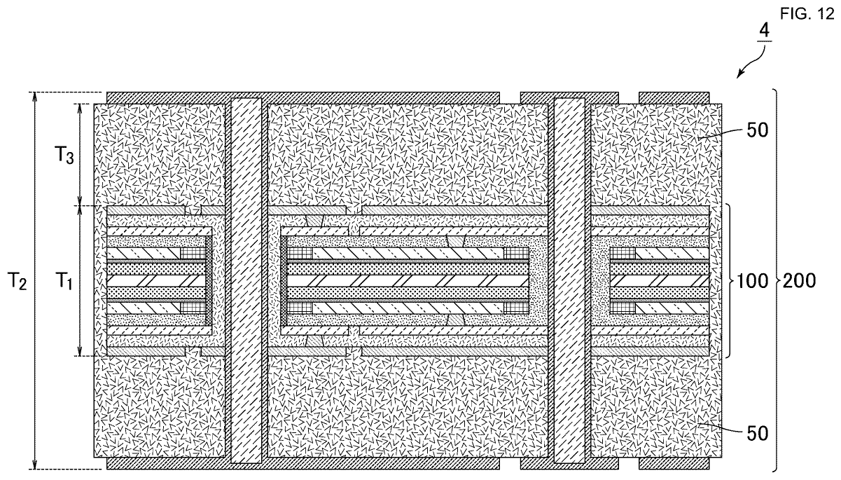

FIG. 12 is a sectional view schematically illustrating an example of the capacitor embedded substrate according to the fourth embodiment of the present disclosure.

In a capacitor embedded substrate 4 illustrated in FIG. 12, when the capacitor element 100 has a thickness T₁, and the wiring substrate 200 has a thickness T₂, the thickness T₂ of the wiring substrate 200 is equal to or more than 2 times the thickness T₁ of the capacitor element 100.

The thickness T₂ of the wiring substrate 200 is preferably equal to or more than 2.5 times the thickness T₁ of the capacitor element 100, and is more preferably equal to or more than 3 times the thickness T₁ of the capacitor element 100. On the other hand, the thickness T₂ of the wiring substrate 200 is, for example, equal to or less than 5 times the thickness T₁ of the capacitor element 100.

The thickness T₂ of the wiring substrate 200 is not particularly limited, but is, for example, equal to or more than 0.6 mm and equal to or less than 2.0 mm.

In the capacitor embedded substrate 4 illustrated in FIG. 12, when the sealing insulating layer 50 has a thickness T₃, the thickness T₃ of the sealing insulating layer 50 provided on one surface of the capacitor element 100 may be the same as or different from the thickness T₃ of the sealing insulating layer 50 provided on the other surface of the capacitor element 100.

Other configurations are the same as those of the first to the third embodiments.

### Fifth Embodiment

In a capacitor embedded substrate according to a fifth embodiment of the present disclosure, the sealing insulating layer constituting the wiring substrate contains a glass cloth. As a result, the rigidity of the capacitor embedded substrate can be increased.

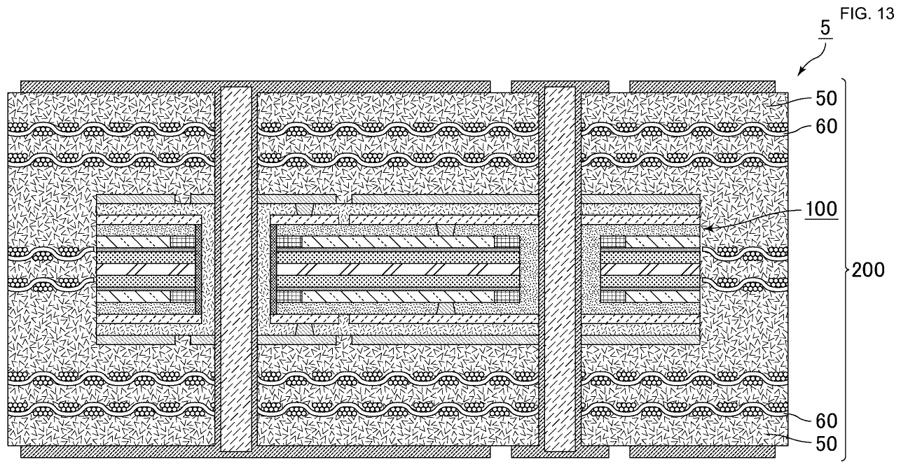

FIG. 13 is a sectional view schematically illustrating an example of the capacitor embedded substrate according to the fifth embodiment of the present disclosure.

In a capacitor embedded substrate 5 illustrated in FIG. 13, the sealing insulating layer 50 constituting the wiring substrate 200 contains a glass cloth 60. In the glass cloth 60, for example, a glass yarn is woven into a grid pattern.

The glass cloth 60 may be contained in the entire sealing insulating layer 50 or may be contained in a part of the sealing insulating layer 50 in an unbalanced manner. In the example illustrated in FIG. 13, a plurality of layers of the glass cloth 60 is stacked with a space therebetween in a thickness direction. The glass cloth 60 of each layer is disposed in a surface direction.

The sealing insulating layer 50 containing the glass cloth 60 is formed by, for example, using prepreg obtained by impregnating a glass cloth with an insulating resin in advance.

Other configurations are the same as those of the first to the fourth embodiments.

Hereinafter, a detailed configuration of the capacitor element 100 will be described.

Inside the sealing layer 20, one capacitor portion 10 may be disposed, or a plurality of capacitor portions 10 may be disposed. When the plurality of capacitor portions 10 is disposed inside the sealing layer 20, the capacitor portions 10 adjacent to each other are preferably divided by a through-groove extending through the capacitor portions 10 in a thickness direction (for example, the up-down direction in FIG. 1). In this case, the through-groove is preferably filled with an insulating material such as the sealing layer 20.

When the capacitor portions 10 adjacent to each other are divided by the through-groove, it is sufficient that the capacitor portions 10 adjacent to each other are physically divided by the through-groove. Therefore, the capacitor portions 10 adjacent to each other may be electrically divided or may be electrically connected. A width of the through-groove, that is, an interval between the capacitor portions 10 adjacent to each other may be constant in the thickness direction or may be decreased in the thickness direction.

When the plurality of capacitor portions 10 is disposed inside the sealing layer 20, the plurality of capacitor portions 10 may be disposed so as to be arranged in a surface direction orthogonal to the thickness direction, may be disposed so as to be stacked in the thickness direction, or may be disposed in combination of both of them. The plurality of capacitor portions 10 may be regularly arranged or may be irregularly arranged. Sizes, shapes, or the like of the capacitor portions 10 may be the same, or the sizes, shapes, or the like of some or all of the capacitor portions 10 may be different. The configuration of each of the capacitor portions 10 is preferably the same, but the capacitor portion 10 having a different configuration may be included.

Examples of a planar shape of the capacitor portion 10 when viewed in the thickness direction include, for example, a polygonal shape such as a rectangular shape (a square or a rectangle), a quadrangle other than a rectangular shape, a triangle, a pentagon, or a hexagon, a circular shape, an elliptical shape, or a combination thereof. In addition, the planar shape of the capacitor portion 10 may be an L shape, a C shape (a square U shape), a step shape, or the like.

The anode plate 11 is preferably made of a valve action metal exhibiting a so-called valve action. Examples of the valve action metal include elemental metals such as aluminum, tantalum, niobium, titanium, and zirconium, and alloys containing at least one of these metals. Among these, aluminum or an aluminum alloy is preferable.

The anode plate 11 preferably has a plate shape and more preferably has a foil shape. As described above, in this specification, a “plate shape” includes a “foil shape”.

The anode plate 11 need only have the porous portion 11B on at least one main surface of the core portion 11A. That is, the anode plate 11 may have the porous portion 11B on only one main surface of the core portion 11A, or may have the porous portions 11B on both the main surfaces of the core portion 11A. Each porous portion 11B is preferably a porous layer formed on a surface of the core portion 11A, and is more preferably an etched layer.

A thickness of the anode plate 11 before etching is preferably equal to or more than 60 μm and equal to or less than 200 μm. A thickness of the non-etched core portion 11A after etching is preferably equal to or more than 15 μm and equal to or less than 70 μm. A thickness of the porous portion 11B is designed according to the withstand voltage and electrostatic capacity required, but a total thickness of the porous portions 11B on both sides of the core portion 11A is preferably equal to or more than 10 μm and equal to or less than 180 μm.

A pore diameter of each porous portion 11B is preferably equal to or more than 10 nm and equal to or less than 600 nm. Note that the pore diameter of the porous portion 11B means a median diameter D50 measured by a mercury porosimeter. The pore diameter of the porous portion 11B can be controlled through adjusting of various conditions of etching, for example.

The dielectric layer 13 provided on a surface of the porous portion 11B is porous reflecting the surface state of the porous portion 11B and has a fine uneven surface shape. The dielectric layer 13 is preferably made of an oxide film of the above-described valve action metal. For example, when an aluminum foil is used as the anode plate 11, a surface of the aluminum foil is anodized (chemically treated) in an aqueous solution containing ammonium adipate or the like, whereby the dielectric layer 13 made of an oxide film can be formed.

A thickness of the dielectric layer 13 is designed according to the withstand voltage and electrostatic capacity required, but is preferably equal to or more than 10 nm and equal to or less than 100 nm.

When the cathode layer 12 includes a solid electrolyte layer, examples of a material constituting the solid electrolyte layer include conductive polymers such as polypyrroles, polythiophenes, and polyanilines. Among these conductive polymers, polythiophenes are preferable, and poly(3,4-ethylenedioxythiophene) called PEDOT is particularly preferable. Further, the above-described conductive polymers may contain a dopant such as polystyrene sulfonic acid (PSS). Note that the solid electrolyte layer preferably includes an inner layer that fills pores (recesses) of the dielectric layer 13 and an outer layer that covers the dielectric layer 13.

A thickness of the solid electrolyte layer from the surface of the porous portion 11B is preferably equal to or more than 2 μm and equal to or less than 20 μm.

The solid electrolyte layer is formed by, for example, a method of using a treatment liquid containing a monomer such as 3,4-ethylenedioxythiophene to form a polymerized film such as a poly(3,4-ethylenedioxythiophene) film on the surface of the dielectric layer 13, or a method of applying a dispersion liquid of a polymer such as poly(3,4-ethylenedioxythiophene) onto the surface of the dielectric layer 13 and drying the dispersion liquid.

The solid electrolyte layer can be formed in a predetermined region through applying of the treatment liquid or dispersion liquid described above to the surface of the dielectric layer 13 by a method such as sponge transfer, screen printing, using a dispenser, or ink jet printing.

When the cathode layer 12 includes a conductor layer, the conductor layer includes at least one layer of a conductive resin layer and a metal layer. The conductor layer may be only the conductive resin layer or may be only the metal layer. The conductor layer preferably covers the entire surface of the solid electrolyte layer.

Examples of the conductive resin layer include a conductive adhesive layer including at least one conductive filler selected from the group consisting of a silver filler, a copper filler, a nickel filler, and a carbon filler.

Examples of the metal layer include a metal plating film and a metal foil. The metal layer is preferably made of at least one metal selected from the group consisting of nickel, copper, silver, and an alloy having these metals as a main component. Note that the “main component” means an element component having the largest weight ratio.

The conductor layer includes, for example, a carbon layer provided on a surface of the solid electrolyte layer and a copper layer provided on a surface of the carbon layer.

The carbon layer is provided so as to electrically and mechanically connect the solid electrolyte layer and the copper layer. The carbon layer can be formed in a predetermined region through applying of a carbon paste to the surface of the solid electrolyte layer by a method such as sponge transfer, screen printing, using a dispenser, or ink jet printing. A thickness of the carbon layer is preferably equal to or more than 2 μm and equal to or less than 20 μm.

The copper layer can be formed in a predetermined region through applying of a copper paste to the surface of the carbon layer by a method such as sponge transfer, screen printing, using a spray, using a dispenser, or ink jet printing. A thickness of the copper layer is preferably equal to or more than 2 μm and equal to or less than 20 μm.

The sealing layer 20 is made of an insulating material. In this case, the sealing layer 20 preferably contains an insulating resin.

Examples of the insulating resin contained in the sealing layer 20 include an epoxy resin and a phenol resin.

The sealing layer 20 preferably further contains a filler such as an inorganic filler.

Examples of the inorganic filler contained in the sealing layer 20 include silica particles and alumina particles.

A layer such as a stress relaxation layer and a moisture-proof film may be interposed between the capacitor portion 10 and the sealing layer 20.

The insulating mask layer 25 is made of an insulating material. In this case, the insulating mask layer 25 preferably contains an insulating resin.

Examples of the insulating resin contained in the insulating mask layer 25 include a polyphenylsulfone resin, a polyethersulfone resin, a cyanate ester resin, a fluororesin (such as tetrafluoroethylene or a tetrafluoroethylene-perfluoroalkyl vinyl ether copolymer), a polyimide resin, a polyamide-imide resin, an epoxy resin, and derivatives and precursors of the above resins.

The insulating mask layer 25 may be made of the same resin as the sealing layer 20. In contrast to the sealing layer 20, when the insulating mask layer 25 contains an inorganic filler, a capacitance effective portion of the capacitor portion 10 may be adversely affected, and thus the insulating mask layer 25 is preferably made of a system of resin alone.

The insulating mask layer 25 can be formed in a predetermined region through applying of a mask material such as a composition containing an insulating resin to the surface of the porous portion 11B by a method such as sponge transfer, screen printing, using a dispenser, or ink jet printing.

The insulating mask layer 25 may be formed on the porous portion 11B at a timing before the dielectric layer 13 or at a timing after the dielectric layer 13.

Materials constituting the first wiring layer 51A and the first wiring layer 51B are preferably the same at least in terms of the type of the materials, but may be different from each other.

Materials constituting the second wiring layer 52A and the second wiring layer 52B are preferably the same at least in terms of the type of the materials, but may be different from each other. The materials constituting the second wiring layer 52A and the second wiring layer 52B are preferably the same as the materials constituting the first wiring layer 51A and the first wiring layer 51B.

Materials constituting the third wiring layer 53A and the third wiring layer 53B are preferably the same at least in terms of the type of the materials, but may be different from each other. The materials constituting the third wiring layer 53A and the third wiring layer 53B are preferably the same as the materials constituting the first wiring layer 51A and the first wiring layer 51B, and the second wiring layer 52A and the second wiring layer 52B.

When the capacitor through anode conductor 30A is electrically connected to the end surface of the anode plate 11 via an anode connection layer, the anode connection layer functions as a barrier layer against the anode plate 11, more specifically, as a barrier layer against the core portion 11A and the porous portion 11B. When the anode connection layer functions as a barrier layer against the anode plate 11, dissolving of the anode plate 11, which is caused at the time of chemical solution treatment for forming a wiring layer such as the first wiring layer 51A, is suppressed, and thus entry of the chemical solution into the capacitor portion 10 is suppressed, whereby the reliability is easily improved.

The anode connection layer preferably includes a layer containing nickel as a main component. In this case, since damage to the metal constituting the anode plate 11 (for example, aluminum) is reduced, the barrier property of the anode connection layer against the anode plate 11 is easily improved.

Note that the capacitor through anode conductor 30A may be directly connected to the end surface of the anode plate 11.

The capacitor embedded substrate of the present disclosure is not limited to the above-described embodiments, and various applications and modifications can be made within the scope of the present disclosure in regard to the configurations of the capacitor element or the wiring substrate, manufacturing conditions of the capacitor embedded substrate, or the like.

In addition, the technique by an indirect through-conductor using a substrate through-conductor in the capacitor embedded substrate of the present disclosure is not limited to being applicable to the electrolytic capacitor described thus far, and is also applicable to other capacitor elements. For example, in a multilayer ceramic capacitor having a first electrode and a second electrode, in a configuration in which the first electrode and the second electrode are embedded inside a substrate so as to face each other in a thickness direction of the substrate, the effect of the present disclosure can also be provided.

The capacitor embedded substrate of the present disclosure can be suitably used as a material constituting a composite electronic component. Such a composite electronic component includes, for example, the capacitor embedded substrate of the present disclosure, and an electronic component electrically connected to the capacitor embedded substrate (for example, an outer electrode layer).

In the composite electronic component, the electronic component electrically connected to the capacitor embedded substrate may be a passive element or an active element. Both the passive element and the active element may be electrically connected to the capacitor embedded substrate, or one of the passive element and the active element may be electrically connected to the capacitor embedded substrate. In addition, a composite of the passive element or the active element may be electrically connected to the capacitor embedded substrate.

Examples of the passive element include an inductor. Examples of the active element include a memory, a graphical processing unit (GPU), a central processing unit (CPU), a micro processing unit (MPU), and a power management IC (PMIC).

The capacitor embedded substrate of the present disclosure has a sheet shape as a whole. Therefore, in the composite electronic component, the capacitor embedded substrate can be treated as a mounting substrate, and the electronic component can be mounted on the capacitor embedded substrate. Moreover, when the electronic component mounted on the capacitor embedded substrate has a sheet shape, the capacitor embedded substrate and the electronic component can be connected in a thickness direction via a through-conductor extending through each electronic component in the thickness direction. As a result, the passive element and the active element can be configured as an inclusive module.

For example, a capacitor element is electrically connected between a voltage regulator including a semiconductor active element and a load to which a converted direct current voltage is supplied, whereby a switching regulator can be formed.

In this specification, the content below is disclosed.

<1> A capacitor embedded substrate including: a wiring substrate; and a capacitor element embedded in the wiring substrate, the capacitor element including: a capacitor portion that includes an anode plate having a porous portion on at least one main surface of a core portion, a dielectric layer on a surface of the porous portion, and a cathode layer on a surface of the dielectric layer, and a sealing layer covering at least one main surface of the capacitor portion; at least one first capacitor through-hole and at least one second capacitor through-hole that do not extend through the wiring substrate but extend through the capacitor element in a thickness direction of the anode plate; a capacitor through anode conductor inside the first capacitor through-hole and electrically connected to an end surface of the anode plate; a first substrate through-hole on an inner side of the first capacitor through-hole and a second substrate through-hole on an inner side of the second capacitor through-hole, the first substrate through-hole and the second substrate through-hole extending through the wiring substrate and the capacitor element in the thickness direction of the anode plate; a substrate through anode conductor on an inner wall surface of the first substrate through-hole, on an inner side of the capacitor through anode conductor, and electrically connected to the anode plate; and a substrate through cathode conductor on an inner wall surface of the second substrate through-hole and electrically connected to the cathode layer.

<2> The capacitor embedded substrate described in <1>, in which a capacitor through cathode conductor is inside the second capacitor through-hole, the capacitor through cathode conductor not electrically connected to the anode plate but electrically connected to the cathode layer, and the substrate through cathode conductor is on an inner side of the capacitor through cathode conductor.

<3> The capacitor embedded substrate described in <1> or <2>, in which the substrate through anode conductor includes a first substrate through anode conductor, the substrate through cathode conductor includes a first substrate through cathode conductor and a second substrate through cathode conductor, and in a plan view in the thickness direction of the anode plate, a center-to-center distance between the first substrate through anode conductor and the first substrate through cathode conductor is equivalent to a center-to-center distance between the first substrate through anode conductor and the second substrate through cathode conductor.

<4> The capacitor embedded substrate described in <3>, in which the substrate through anode conductor further includes a second substrate through anode conductor, and in the plan view in the thickness direction of the anode plate, the center-to-center distance between the first substrate through anode conductor and the first substrate through cathode conductor is equivalent to a center-to-center distance between the second substrate through anode conductor and the first substrate through cathode conductor.

<5> The capacitor embedded substrate described in any one of <1> to <4>, in which the substrate through anode conductor includes a first substrate through anode conductor and a second substrate through anode conductor, the substrate through cathode conductor includes a first substrate through cathode conductor, and in the plan view in the thickness direction of the anode plate, a center-to-center distance between the first substrate through anode conductor and the first substrate through cathode conductor is equivalent to a center-to-center distance between the second substrate through anode conductor and the first substrate through cathode conductor.

<6> The capacitor embedded substrate described in any one of <1> to <5>, in which a thickness of the wiring substrate is equal to or more than 2 times a thickness of the capacitor element.

<7> The capacitor embedded substrate described in any one of <1> to <6>, in which the wiring substrate includes a sealing insulating layer, and the sealing insulating layer contains a glass cloth.

### REFERENCE SIGNS LIST

1, 1a, 2, 3, 4, 5 capacitor embedded substrate
10 capacitor portion
11 anode plate
11A core portion
11B porous portion
12 cathode layer
13 dielectric layer
20 sealing layer
21 first sealing layer
22 second sealing layer
25 insulating mask layer
30A capacitor through anode conductor
30B capacitor through cathode conductor
35A first capacitor through-hole
35B second capacitor through-hole
40A substrate through anode conductor
40A1 first substrate through anode conductor
40A2 second substrate through anode conductor
40B substrate through cathode conductor
40B1 first substrate through cathode conductor
40B2 second substrate through cathode conductor
45A first substrate through-hole
45B second substrate through-hole
48A first resin filling portion
48B second resin filling portion
50 sealing insulating layer
51A, 51B first wiring layer
52A, 52B second wiring layer
53A, 53B third wiring layer
55A anode via conductor
55B cathode via conductor
60 glass cloth
100, 100a capacitor element
200 wiring substrate
T₁ thickness of capacitor element
T₂ thickness of wiring substrate
T₃ thickness of sealing insulating layer
α center-to-center distance between first substrate through anode conductor and first substrate through cathode conductor
β center-to-center distance between first substrate through anode conductor and second substrate through cathode conductor
γ center-to-center distance between second substrate through anode conductor and first substrate through cathode conductor

1. A capacitor embedded substrate comprising:
a wiring substrate; and
a capacitor element embedded in the wiring substrate, the capacitor element including:
a capacitor portion that includes an anode plate having a porous portion on at least one main surface of a core portion, a dielectric layer on a surface of the porous portion, and a cathode layer on a surface of the dielectric layer, and
a sealing layer covering at least one main surface of the capacitor portion;
at least one first capacitor through-hole and at least one second capacitor through-hole that do not extend through the wiring substrate but extend through the capacitor element in a thickness direction of the anode plate;
a capacitor through anode conductor inside the first capacitor through-hole and electrically connected to an end surface of the anode plate;
a first substrate through-hole on an inner side of the first capacitor through-hole and a second substrate through-hole on an inner side of the second capacitor through-hole, the first substrate through-hole and the second substrate through-hole extending through the wiring substrate and the capacitor element in the thickness direction of the anode plate;
a substrate through anode conductor on an inner wall surface of the first substrate through-hole, on an inner side of the capacitor through anode conductor, and electrically connected to the anode plate; and
a substrate through cathode conductor on an inner wall surface of the second substrate through-hole and electrically connected to the cathode layer.

2. The capacitor embedded substrate according to claim 1, further comprising:
a capacitor through cathode conductor inside the second capacitor through-hole, the capacitor through cathode conductor not electrically connected to the anode plate but electrically connected to the cathode layer, and wherein
the substrate through cathode conductor is on an inner side of the capacitor through cathode conductor.

3. The capacitor embedded substrate according to claim 1, wherein
the substrate through anode conductor includes a first substrate through anode conductor,
the substrate through cathode conductor includes a first substrate through cathode conductor and a second substrate through cathode conductor, and
in a plan view in the thickness direction of the anode plate, a center-to-center distance between the first substrate through anode conductor and the first substrate through cathode conductor is equivalent to a center-to-center distance between the first substrate through anode conductor and the second substrate through cathode conductor.

4. The capacitor embedded substrate according to claim 3, wherein
the substrate through anode conductor further includes a second substrate through anode conductor, and
in the plan view in the thickness direction of the anode plate, the center-to-center distance between the first substrate through anode conductor and the first substrate through cathode conductor is equivalent to a center-to-center distance between the second substrate through anode conductor and the first substrate through cathode conductor.

5. The capacitor embedded substrate according to claim 1, wherein
the substrate through anode conductor includes a first substrate through anode conductor and a second substrate through anode conductor,
the substrate through cathode conductor includes a first substrate through cathode conductor, and
in a plan view in the thickness direction of the anode plate, a center-to-center distance between the first substrate through anode conductor and the first substrate through cathode conductor is equivalent to a center-to-center distance between the second substrate through anode conductor and the first substrate through cathode conductor.

6. The capacitor embedded substrate according to claim 1, wherein a thickness of the wiring substrate is equal to or more than 2 times a thickness of the capacitor element.

7. The capacitor embedded substrate according to claim 1, wherein a thickness of the wiring substrate is equal to or more than 2.5 times a thickness of the capacitor element, and is equal to or less than 5 times the thickness of the capacitor element.

8. The capacitor embedded substrate according to claim 1, wherein the wiring substrate includes a sealing insulating layer covering at least one main surface of the capacitor element.

9. The capacitor embedded substrate according to claim 8, wherein the sealing insulating layer contains a glass cloth.

10. The capacitor embedded substrate according to claim 8, wherein the sealing insulating layer contains a plurality of layers of glass cloth stacked with a space therebetween in the thickness direction.

11. The capacitor embedded substrate according to claim 1, further comprising:
a first wiring layer electrically connected to the capacitor through anode conductor; and
a second wiring layer electrically connected to the cathode layer.

12. The capacitor embedded substrate according to claim 11, wherein the second wiring layer is connected to the cathode layer via a cathode via conductor extending through the sealing layer.

13. The capacitor embedded substrate according to claim 11, further comprising:
a third wiring layer connected to the first wiring layer via an anode via conductor; and
a fourth wiring layer electrically connected to the substrate through cathode conductor.

14. The capacitor embedded substrate according to claim 13, further comprising:
a fifth wiring layer electrically connected to the substrate through anode conductor; and
a sixth wiring layer electrically connected to the substrate through cathode conductor.

15. The capacitor embedded substrate according to claim 14, wherein
the fifth wiring layer is electrically connected to the anode plate via the substrate through anode conductor, the third wiring layer, an anode via conductor, the first wiring layer, and the capacitor through anode conductor, and
the sixth wiring layer is electrically connected to the cathode layer via the substrate through cathode conductor, the fourth wiring layer, the second wiring layer, and a cathode via conductor.
